(19) United States
(12) Patent Application Publication
(10) Pub. No.: US 2025/0235866 A1
(43) Pub. Date: Jul. 24, 2025

(54) FEEDBACK CONTROLLED MICROFLUIDIC PIEZOELECTRIC ACTUATION ASSEMBLY AND USE

(71) Applicant: Astrin Biosciences, Inc., St. Paul, MN (US)

(72) Inventors: Mahdi Ahmadi, Minneapolis, MN (US); Kaylee Judith Kamalanathan, Woodbury, MN (US); Nicholas Heller, Minneapolis, MN (US); Jayant Parthasarathy, Excelsior, MN (US); Jiarong Hong, New Brighton, MN (US)

(73) Assignee: Astrin Biosciences, Inc., St. Paul, MN (US)

(21) Appl. No.: 18/855,526

(22) PCT Filed: Apr. 21, 2023
(86) PCT No.: PCT/US2023/019403

§ 371 Date: Oct. 9, 2024

Related U.S. Application Data
(60) Provisional application No. 63/363,422, filed on Apr. 22, 2022.

(51) Int. Cl. B01L 3/00

(52) U.S. Cl. CPC B01L 3/502761; B01L 3/502715; B01L 2200/0652; B01L 2200/143; B01L 2300/0663; B01L 2300/0864; B01L 2400/0415

(57) ABSTRACT

Provided herein is a microfluidic chip for sorting cells with an actuator assembly that relies on one or more feedback-controlled piezoelectric actuators to divert sample fluid flowing along a sample fluid path in a sample fluid line into one or more desired outlets. Also provided are methods of use.

### BACKGROUND

The manipulation and separation of particles, especially living cells, is an essential step for many biological and medical applications, including isolation and detection of sparse cancer cells, the concentration of cells from dilute suspensions, separation of cells according to specific properties, and trapping and positioning of individual cells for characterization. Cells are tiny objects measured on a nanometer or micrometer scale. Accordingly, devices that manipulate and separate cells must be precision instruments capable of moving small volumes of material. Manufacturing and operating these precision instruments is challenging because even minuscule variations in one or more components of a separation device can dramatically reduce the device's effectiveness. The useable life of cell separation devices is also limited because wearing and other changes to the device over time can also reduce the device's effectiveness and there are no mechanisms for reusing the more durable components of the device. Accordingly, it is desirable to produce a precision separation device that is resilient to manufacturing defects, wearing, and other variations and includes one or more reusable components.

### SUMMARY

Provided herein is a microfluidic chip for sorting cells and other types of particles with an actuator assembly that relies on one or more feedback-controlled piezoelectric actuators to divert fluid paths into one or more desired outlets. The feedback-controlled piezoelectric actuators can compensate for variations in one or more components of the microfluidic chip and can include one or more reusable components. Therefore, the feedback-controlled piezoelectric actuators are more precise and durable than other cell separation systems.

In a first example embodiment, a microfluidic chip for sorting cells is provided. The microfluidic chip can include a sample fluid line including an inlet microfluidic channel and multiple outlet microfluidic channels positioned opposite the inlet microfluidic channel. The multiple outlet microfluidic channels can include one or more waste outlet channels and one or more sorted outlet channels.

The microfluidic chip can also include one or more active sheath fluid filled chambers placed at an angle to the sample fluid line and an actuator assembly adjacent to one of the one or more active sheath fluid filled chambers. The actuator assembly can include a piezoelectric actuator that pushes against the one or more active sheath fluid filled chamber to dispense an amount of active sheath fluid that diverts a portion of a sample fluid to the one or more sorted outlet channels.

The actuator assembly can also include a piezoelectric controller that causes the piezoelectric actuator to engage with the one or more active sheath fluid filled chambers in response to a trigger and a feedback sensor that determines a contact force exerted by the piezoelectric actuator on the one or more active sheath fluid filled chambers.

In some instances, the actuator assembly further comprises a bias screw configured to rotate up and down within a bias screw holder to establish a contact force with a membrane in contact with the piezoelectric actuator. The actuator assembly can also include an actuation voltage provided by the piezoelectric controller configured to trigger the piezoelectric actuator to elongate in proportion to the voltage. A greater actuation voltage can correspond to greater elongation of an elongated piezoelectric actuator. The elongated piezoelectric actuator can push against the membrane to deflect the membrane downward into one or more active sheath fluid filled chambers.

In some instances, the feedback sensor is disposed between the piezoelectric actuator and the bias screw. The feedback sensor can be configured to record an amount of force exerted by the bias screw and the piezoelectric actuator as the contact force exerted by the piezoelectric actuator on the one or more active sheath fluid filled chambers.

In some instances, the feedback sensor is further configured to, during actuation, record an increased amount of force exerted by the bias screw and the piezoelectric actuator. An adjustment of the bias screw and/or an actuator voltage can be based on the feedback sensor determining a change between the amount of force and the increased amount of force.

In some instances, the actuator assembly further comprises a motor coupled to a bias screw configured to establish a contact force with a membrane in contact with the piezoelectric actuator based on a derivation of the sample fluid in the sample fluid path. The actuator assembly can also include an actuation voltage provided by the piezoelectric controller configured to trigger the piezoelectric actuator to elongate in proportion to the voltage. A greater actuation voltage can correspond to greater elongation of an elongated piezoelectric actuator. The elongated piezoelectric actuator can push against the membrane to deflect the membrane downward into one or more active sheath fluid filled chambers.

In some instances, the piezoelectric actuator is configured to control a diversion of the portion of the sample fluid into one or more sorted outlet channels by adjusting the contact force.

In some instances, the piezoelectric actuator increases the contact force by increasing an actuation voltage or changing a position of a bias screw configured to elongate the piezoelectric actuator.

In some instances, the actuator assembly is integrated into a reusable unit that is removable from the microfluidic chip.

In some instances, the microfluidic chip can also include a trigger assembly connected to the piezoelectric controller, the trigger assembly including an optical sensor that detects a cell of interest in the sample. The trigger assembly can be configured to transmit the trigger to the piezoelectric controller in response to detecting the cell of interest.

In some instances, the trigger assembly is further configured to detect the cell of interest in at least two consecutive frames captured by the optical sensor and calculate a velocity of the sample within the inlet microfluidic channel. The trigger assembly can be further configured to determine a travel time for the cell of interest between the optical sensor field of view and a sorting zone based on the velocity and a length of the microfluidic channel between the optical sensor field of view and the sorting zone and transmit the trigger to the piezoelectric controller when the travel time expires.

In some instances, the trigger assembly is further configured to detect the cell of interest at a position close to the one or more sorted outlet channels, and transmit the trigger to the piezoelectric controller when the cell of interest is detected such that the cell of interest is pushed into the one or more sorted outlet channels.

In an aspect, a microfluidic chip comprises one waste outlet channel and one sorted outlet channel.

In another example embodiment, an actuator assembly for diverting a portion of a sample fluid is provided. The actuator assembly can be integrated into a reusable unit that is configured to attach to a portion of a microfluidic chip. The actuator assembly can include the microfluidic chip including a sample fluid line including an inlet microfluidic channel and multiple outlet microfluidic channels positioned opposite the inlet microfluidic channel. The multiple outlet microfluidic channels can include one or more waste outlet channels and one or more sorted outlet channels. The actuator assembly can include one or more active sheath fluid filled chambers placed at an angle to the sample fluid line. The actuator assembly can be adjacent to one of the one or more active sheath fluid filled chambers.

The actuator assembly can include a piezoelectric actuator that pushes against the one or more active sheath fluid filled chambers to dispense an amount of active sheath fluid that diverts a portion of a sample fluid to one or more sorted outlet channels. The actuator assembly can also include a piezoelectric controller that causes the piezoelectric actuator to engage with the one or more active sheath fluid filled chambers in response to a trigger and a feedback sensor that determines a contact force exerted by the piezoelectric actuator on the one or more active sheath fluid filled chambers.

In some instances, the actuator assembly can include a bias screw configured to rotate up and down within a bias screw holder to establish a contact force with a membrane in contact with the piezoelectric actuator The actuator assembly can also include an actuation voltage provided by the piezoelectric controller configured to trigger the piezoelectric actuator to elongate in proportion to the voltage. A greater actuation voltage can correspond to greater elongation of an elongated piezoelectric actuator. The elongated piezoelectric actuator can push against the membrane to deflect the membrane downward into one or more active sheath fluid filled chambers.

In some instances, the actuator assembly can include a motor coupled to a bias screw configured to establish a contact force with a membrane in contact with the piezoelectric actuator based on a derivation of the sample fluid in the sample fluid path. The actuator assembly can also include an actuation voltage provided by the piezoelectric controller configured to trigger the piezoelectric actuator to elongate in proportion to the voltage, wherein a greater actuation voltage corresponds to greater elongation of an elongated piezoelectric actuator. The elongated piezoelectric actuator can push against the membrane to deflect the membrane downward into one or more active sheath fluid filled chambers.

In some instances, the feedback sensor is disposed between the piezoelectric actuator and the bias screw. The feedback sensor can be configured to record an amount of force exerted by the bias screw and the piezoelectric actuator as the contact force exerted by the piezoelectric actuator on the one or more active sheath fluid filled chambers. The feedback sensor can also be configured to, during actuation, record an increased amount of force exerted by the bias screw and the piezoelectric actuator. The feedback sensor can also be configured to determine an adjustment of the bias screw and/or an actuator voltage based on a change between the amount of force and the increased amount of force.

In some instances, the piezoelectric actuator is configured to control a diversion of the portion of the sample fluid into one or more sorted outlets channel by adjusting the contact force.

In some instances, the piezoelectric actuator increases the contact force by increasing an actuation voltage or changing a position of a bias screw configured to elongate the piezoelectric actuator.

In some instances, the actuator assembly can include a trigger assembly connected to the piezoelectric controller, the trigger assembly including an optical sensor that detects a cell of interest in the sample. The trigger assembly can be configured to transmit the trigger to the piezoelectric controller in response to detecting the cell of interest.

In some instances, the trigger assembly is further configured to detect the cell of interest in at least two consecutive frames captured by the optical sensor and calculate a velocity of the sample within the inlet microfluidic channel. The trigger assembly can be further configured to determine a travel time for the cell of interest between a field of view of the optical sensor and a sorting zone based on the velocity and a length of the microfluidic channel between the optical sensor field of view and the sorting zone, and transmit the trigger to the piezoelectric controller when the travel time expires.

In an aspect, the actuator assembly can comprise one waste outlet channel and one sorted outlet channel.

In another example embodiment, a method for sorting cells is provided. The method can include inserting a sample into a sample fluid line in the microfluidic chip as described herein. The sample fluid line can include an inlet microfluidic channel that receives the sample and multiple outlet microfluidic channels positioned opposite the inlet microfluidic channel. The multiple outlet microfluidic channels can include one or more waste outlet channels and one or more sorted outlet channels.

The method can also include causing, by the piezoelectric controller, the piezoelectric actuator to push against one or more active sheath fluid filled chambers. The method can also include dispensing, by the piezoelectric actuator, an amount of active sheath fluid from the one or more active sheath fluid filled chambers to divert a portion of a sample fluid to one or more sorted outlet channels. The method can also include determining, by the feedback sensor, a contact force exerted by the piezoelectric actuator on the one or more active sheath fluid filled chambers.

In some instances, the microfluidic chip further includes a membrane in contact with the piezoelectric actuator and a bias screw within a holder. The method can also include rotating the bias screw in a downward direction within the holder to elongate the piezoelectric actuator and deflecting, by the elongated piezoelectric actuator, the membrane downward into the one or more active sheath fluid filled chambers to dispense the amount of fluid from the one or more active sheath fluid filled chambers.

In some instances, the method can include adjusting, by the piezoelectric actuator, the contact force to control a diversion of the portion of the sample fluid into one or more sorted outlet channels.

In some instances, the method can include increasing, by the piezoelectric actuator, the contact force by increasing an actuation voltage or changing a position of a bias screw configured to elongate the piezoelectric actuator.

In some instances, the feedback sensor is disposed between the piezoelectric actuator and the bias screw. The method can also include recording, by the feedback sensor an amount of force exerted by the bias screw and the piezoelectric actuator as the contact force exerted by the piezoelectric actuator on one or more active sheath fluid filled chambers. The method can also include, during actuation, recording, by the feedback sensor, an increased amount of force exerted by the bias screw and the piezoelectric actuator. The method can also include determining, by the feedback sensor an adjustment of the bias screw and/or an actuator voltage based on a change between the amount of force and the increased amount of force.

In some instances, the actuator assembly is integrated into a reusable unit. The method can also include removing the reusable unit including the actuator assembly from the microfluidic chip.

In some instances, the microfluidic chip further includes a trigger assembly connected to the piezoelectric controller. The method can also include detecting, by an optical sensor included in the trigger assembly, a cell of interest in the sample, and transmitting, by the trigger assembly, the trigger to the piezoelectric controller in response to detecting the cell of interest.

In some instances, the method can include detecting, by the trigger assembly, the cell of interest in at least two consecutive frames captured by the optical sensor. The method can also include calculating a velocity of the sample within the inlet microfluidic channel. The method can also include determining a travel time for the cell of interest between a field of view optical sensor and a sorting zone based on the velocity and a length of the microfluidic channel between the optical sensor field of view and the sorting zone. The method can also include transmitting the trigger to the piezoelectric controller when the travel time expires.

The detecting can be based on an output of a classification model. The methods can further comprise training the classification model using a training dataset that includes multiple images labeled with different cell types, wherein the output of the classification model includes a prediction for a cell type of one or more detected cells or the image data of the at least two consecutive frames. The methods can further comprise training the classification model using a training dataset that includes multiple images labeled as including healthy cells and multiple images labeled as including other or unhealthy cells, wherein the output of the classification model includes a prediction of a type of one or more detected cells or the image data of the at least two consecutive frames.

In some instances, the active sheath fluid has a different refractive index than the sheath fluid.

In another example embodiment, a method for sorting cells using a cell sorting device is provided. The cell sorting device can include a sample fluid line, the sample fluid line including an inlet channel that receives the sample, multiple outlet channels positioned opposite the inlet microfluidic channel, the multiple outlet channels including one or more waste outlet channels and one or more sorted outlet channels. The cell sorting device can also include one or more active sheath fluid filled chambers placed at an angle to the sample fluid line. The method can include inserting a sample fluid containing cells though the sample fluid line wherein the active sheath fluid has a different refractive index than the sheath fluid, visualizing a difference in refractive indices of the active sheath fluid and the sample fluid, and collecting the sorted cells.

### BRIEF DESCRIPTION OF THE DRAWINGS

Various objectives, features, and advantages of the disclosed subject matter can be more fully appreciated with reference to the following detailed description of the disclosed subject matter when considered in connection with the following drawings, in which like reference numerals identify like elements.

FIG. 1 shows a schematic of the microfluidic chip for cell sorting showing the inlet microfluidic channel to the sorting zone and an actuator assembly adjacent to the sorting zone.

FIG. 2A-2B shows a design of the microfluidic chip showing sample fluid, sheath fluid, and active sheath fluid having active sheath fluid path for sorting the target cells or target particles at right, active sheath fluid filled chambers in center, and outlet microfluidic channels at left.

FIG. 3 shows a fabricated single cell/particle sorting device: it shows the sample fluid (bright) at left that is covered by sheath fluid (dark). Two active sheath fluid paths join from top and bottom and squeeze the sample fluid flowing through a sample fluid line, forming the sample fluid path, which flows into the center outlet. At the right side the waste will go straight out, and the bottom line will collect the sorted cells/particles. The top channel is bidirectional and can be set to be an output or an input for removing blockage.

FIG. 4 shows an assembled microfluidic chip with the bias screw, bias screw holder, feedback sensor and the piezoelectric actuator.

FIGS. 5A-D show images of a channel with varying BSA concentrations coming from the center channel and PBS coming from the upper and lower channels. FIG. 5A shows PBS in both channels. FIG. 5B shows 1% BSA in the center channel. FIG. 5C shows 3.5% BSA in the center channel. FIG. 5D shows 7% BSA in the center channel.

FIG. 6 shows an image of a channel outlet. The sample fluid line through which the sample fluid flows along a sample fluid path has cells in 7% BSA, the sheath fluid is 0% BSA, and the active sheath flow fluid is 7% BSA.

FIG. 7 shows a graph of the refractive indices of BSA dissolved in PBS.

The drawings are not necessarily to scale, or inclusive of all elements of a system, emphasis instead generally being placed upon illustrating the concepts, structures, and techniques sought to be protected herein.

FIG. 8 shows a design for the reduction of the chance of clumps blocking the outlets. In the following configuration there are two outlets: one is designated for unwanted particles (waste) and one is designated for the target cell/particles (“CTC”). Less outlets at the sorting fork plus moving the target outlet downward reduces the chance of clogging in the sorting area.

### DETAILED DESCRIPTION

The details of one or more variations of the subject matter described herein are set forth in the accompanying drawings and the description below. Other features and advantages of the subject matter described herein will be apparent from the description and drawings, and from the claims. The disclosed subject matter is not, however, limited to any particular embodiment disclosed.

Provided herein is a microfluidic chip for sorting cells with an actuator assembly that relies on one or more feedback-controlled piezoelectric actuators to divert fluid paths into the desired outlets. The microfluidic chip can include: a sample fluid line including an inlet microfluidic channel and multiple outlet microfluidic channels positioned opposite the inlet microfluidic channel, the multiple outlet microfluidic channels including one or more waste outlet channel and one or more sorted outlet channels; one or more active sheath fluid filled chambers placed at an angle to the sample fluid line; and an actuator assembly adjacent to one of the one or more active sheath fluid filled chambers, the actuator assembly including: a piezoelectric actuator that pushes against the one or more active sheath fluid filled chambers to dispense an amount of active sheath fluid that diverts a portion of a sample fluid to the sorted outlet channel; a piezoelectric controller that causes the piezoelectric actuator to engage with the one or more active sheath fluid filled chambers in response to a trigger; and a feedback sensor that determines a contact force exerted by the piezoelectric actuator on the one or more active sheath fluid filled chambers.

### Microfluidic Chip

The microfluidic chip for cell sorting described herein can include a sample fluid line, one or more inlet microfluidic channels, one or more outlet microfluidic channels, one or more active sheath fluid filled chambers, and an actuator assembly.

Microfluidics systems are miniaturized devices that offer fast fluid collection speeds with high efficiencies, which can be used to collect, divert, or transport small fluid and or sample sizes. A microfluidics system can be e.g., flow-based channel microfluidics, electric-based digital microfluidics (DMF), or other suitable systems. In some embodiments, the microfluidic system can include components such as channels, reservoirs, valves, collection chambers, filters, fluidic interconnects, diffusers, and other microfluidic components. These microfluidic components typically have dimensions between a few micrometers and a few hundreds of micrometers. The small dimensions of the components of the microfluidic system can enable efficient management of fluid movement and minimize the physical size, response time, and waste (i.e., fluid and or sample loss) within the system.

A microfluidic system can control flow, direction, and collection of a fluid (e.g., sample fluid, active sheath fluid, or sheath fluid) path. A fluid path describes the flow of fluid (e.g., sample fluid, active sheath fluid, or sheath fluid) through the device and it can be linear or otherwise. A fluid path can be a sample fluid path and can flow along an axis (e.g., horizontal) of the microfluidic chip for cell sorting. A fluid path can be a sheath fluid path which can flow along an axis (e.g., horizontal) of the microfluidic chip for cell sorting. A fluid path can also describe the path of the active sheath fluid takes within the microfluidic chip for cell sorting (active sheath fluid and active sheath fluid filled chambers discussed in greater details below).

Active sheath fluid or active sheath flow can prime the chip or microfluidics initially to remove air. Active sheath fluid or active sheath flow can also act as a secondary sheath flow the keeps the sample stream focused. This fluid or flow can be actuated by the piezoelectric actuator to become an asymmetric sheath flow and change the pressure gradient such that the stream is bent. That is, the active sheath fluid or active sheath flow can push the cells to the desired chamber. Active sheath fluid or active sheath flow can be used to accommodate of the changing flow conditions in biological samples, such as blood samples which can clog due to cell agglomeration or large debris or to accommodate bubble induced pressure fluctuation and cell deposition within a channel. The flow rate of the active sheath flow can be adjusted to ensure cells or particles are still transported to the desired channel under changing flow conditions.

A sample fluid can be added to one or more inlet microfluidic channels of a microfluidic device. An inlet microfluidic channel can be the locale for input of a sample fluid or portion thereof in the microfluidic system and the inlet microfluidic cannel can be positioned at a proximate end of a sample fluid line. A sample fluid can contain target cells or target particles along with non-target cells or non-target particles. The target cells or particles can be sorted to a sorted outlet. The non-target cells and non-target particles can be sent to a waste outlet. An inlet microfluidic channel can be any suitable microfluidic inlet for the input of fluids and/or biological samples into a microfluidic system.

A microfluidic chip can include a sample fluid line, which can be any suitable microfluidic channel. A sample fluid can flow along a sample fluid path in a sample fluid line. A sheath fluid path can also flow along a sample fluid line. A sample fluid line can be a portion of the microfluidic chip between an inlet microfluidic channel and multiple outlet microfluidic channels.

A fluid (e.g., a sample fluid) can flow along a fluid path (e.g., a sample fluid path) from an inlet microfluidic channel to one or more outlet microfluidic channels positioned opposite the inlet microfluidic channel. In other words, the inlet microfluidic channel can be positioned at a proximal end of a sample fluid line and the multiple outlet channels can be positioned at a distal end of the sample fluid line.

Multiple outlet microfluidic channels can be any suitable microfluidic outlet for outflow of fluids and/or biological samples from a microfluidic system. Multiple outlet microfluidic channels can be 2, 3, 4, 5, 6, or more outlet microfluidic channels. The multiple outlet microfluidic channels can include one or more (e.g., 1, 2, 3, or more) waste outlet channels. A waste outlet channel can be a center waste outlet positioned in line with a sample fluid line at the distal end of said sample fluid line. A sample fluid line can comprise a portion of a microfluidic chip disposed between the inlet microfluidic channel and one or more outlet microfluidic channels and can be any suitable microfluidic channel. A waste outlet channel can be an upper waste outlet or a lower waste outlet positioned at an angle (e.g., about 10, 15, 20, 25, 30, 35, 40, 45, 50, 55, 60, 65, 70, 75, 80, 85, 90, 95, 100, 105, 11, 115, 120, 125, 130, 135, 140, 145, 150, 155, 160°) to the sample fluid line. In some embodiments, an angle between an upper waste outlet and a lower waste outlet can be optimized to avoid flow separation under differ flow rates. In some embodiments, an outlet channel can function as additional cell sorting outlets'. For example, a device can comprise one outlet channel that can be used for sorting cell clusters, a second outlet for sorting specific single cells, and a third outlet for waste. In another embodiment, a device can comprise one outlet channel that can be used for sorting one cell type, a second outlet for sorting a second cell type, and a third outlet for waste.

In some embodiments, an outlet channel can function as an anticlog outlet to clear any blockages in an inlet channel. Clogs can be removed by blocking the other outlet channels and forcing any remnant fluid (e.g., sample fluid, active sheath fluid, or sheath fluid) in the channel out the remaining outlet channel. The multiple outlet microfluidic channels can include one or more (e.g., 1, 2, 3, or more) sorted outlet channels. In some embodiments, target cells or target particles within a sample fluid can be identified and thus diverted to a sorted outlet channel. A sorted outlet channel can be positioned at an angle to (e.g., about 10, 15, 20, 25, 30, 35, 40, 45, 50, 55, 60, 65, 70, 75, 80, 85, 90, 95, 100, 105, 11, 115, 120, 125, 130, 135, 140, 145, 150, 155, 160°) to the sample fluid line.

In some aspects, a device can have 1 waste outlet channel and 1 sorted outlet channel. In some aspects, a device can have 1 or 2 waste outlet channels and 1 or 2 sorted outlet channels. In some aspects, a device can have 1, 2, or 3 waste outlet channels and 1, 2 or 3 sorted outlet channels.

The sample fluid can be continuous flow, water-in-oil droplets, or any other suitable sample. The sample fluid can flow through the sample fluid line establishing a sample fluid path. A sample fluid can flow at a rate of 1 μL/min to about 20 μL/min (e.g., 1, 2, 3, 4, 5, 6, 7, 8, 9, 10, 11, 12, 13, 14, 15, 16, 17, 18, 19, or 20 μL/min). A sample fluid can flow at a rate of about 1 mL/min to about 10 mL/min (e.g., about 1, 2, 3, 4, 5, 6, 7, 8, 9, or 10 mL/min).

In some embodiments, one or more sheath fluids can be added to the system to further center the sample fluid path flowing through the sample fluid line. Depending on experimental needs, different formulations of sheath fluid can be used (e.g., water, pre-mixed phosphate-buffered saline from e.g., Leinco Technologies, Hepes-buffered saline, which is particularly useful for high-pressure cell sorting, or any other suitable cell compatible fluid). In some embodiments, the sheath fluid and the sample fluid do not mix and each retain their own path. Adding a small amount of surfactant such as 2-phenoxyethanol (e.g., about 0.05, 0.1, 0.2, 0.5, 1.0% or more) can help serve as a surfactant to help keep the system flowing by reducing the surface tension. Sheath fluid can be added to one or more focusing inlets. A focusing inlet can be proximate to the sample inlet microfluidic channel. Sheath fluid can be added to one or more focusing inlets prior to, simultaneously with, or after the sample fluid is introduced to an inlet microfluidic channel at a proximal end of a sample fluid line. In one embodiment the sheath fluid can focus the cells in the perpendicular direction of the channel (focus from left and right and top and bottom), which can achieve better cell focus. In some embodiments, once the sheath fluid is running at laminar flow, the sample containing cells or particles to be sorted is injected into the center of the sample fluid path at a slightly higher pressure (e.g., about 1, 2, 5, 10, 20, 30% or higher). The principles of hydrodynamic focusing cause the cells to align, in the direction of flow of the sample fluid in the sample fluid path through the sample fluid line.

A microfluidic chip can include one or more active sheath fluid filled chambers for modulating the flow of active sheath fluid path. One or more active sheath fluid filled chambers can be placed at an angle to a sample fluid line. A active sheath fluid filled chamber can be placed at an angle of about 10, 15, 20, 25, 30, 35, 40, 45, 50, 55, 60, 65, 70, 75, 80, 85, 90, 95, 100, 105, 11, 115, 120, 125, 130, 135, 140, 145, 150, 155, 160° from the sample fluid line. A active sheath fluid filled chamber can be, e.g., a continuously-fed active sheath fluid fed chamber. Active sheath fluid can comprise any suitable fluid including mixtures including bovine serum albumin (BSA), phosphate buffered saline (PBS), proteins commonly found in blood and/or other bodily fluids (such as, but not limited to, globulins and fibrinogen), biocompatible colored dyes (e.g., crystal violet), HEPES, EDTA, fetal bovine serum, or combinations thereof. In some embodiments, active sheath fluid can be a mixture of about 1, 2, 3, 4, 5, 6, 7, 8, 9, 10, 11, 12, 13, 14, or 15% albumin (e.g., bovine serum albumin) or fetal bovine serum in PBS. In an embodiment, the active sheath fluid comprises about 1, 2, 3, 4, 5, 6, 7, 8, 9, 10, 11, 12, 13, 14, or 15% albumin (e.g., bovine serum albumin) or fetal bovine serum in PBS, while the sample fluid does not contain albumin or fetal bovine serum (e.g., the sample fluid is PBS). In an embodiment, the active sheath fluid and sample fluid comprises about 1, 2, 3, 4, 5, 6, 7, 8, 9, 10, 11, 12, 13, 14, or 15% albumin (e.g., bovine serum albumin) or fetal bovine serum in PBS, while the sheath fluid does not contain albumin or fetal bovine serum (e.g., the sample fluid is PBS). In some embodiments, the active sheath fluid and the sheath fluid can be the same fluid and the sample fluid can be a different fluid. Where only a single boundary is desired the sample and active sheath fluids can be different and the sheath fluid could match one of them. In some embodiments, the sheath fluid and the sample fluid can be the same fluid and the active sheath fluid can be a different fluid. In some embodiments, the sample fluid, active sheath fluid, and sheath fluid can be the same fluid. In some embodiments, the sample fluid, active sheath fluid, and sheath fluid can each be a different fluid.

Different refractive indices between and among sheath fluid, active sheath fluid, and/or sample fluid can help visualize the boundaries between any one, two, and/or three of the fluids, which can allow the piezoelectric actuator to be set properly to provide the correct amount of pressure to push the sample fluid to the outlets.

An additional benefit of differing refractive indices can be visualizing the streamlines and can provide awareness if the flow patterns of the fluids are changed in the chip due to another unknown issue.

In an embodiment, a sample fluid is any suitable fluid including mixtures including bovine serum albumin (BSA), phosphate buffered saline (PBS), proteins commonly found in blood and/or other bodily fluids (such as, but not limited to, globulins and fibrinogen), biocompatible colored dyes (e.g., crystal violet), fetal bovine serum or combinations thereof. In some embodiments, sample fluid can be a mixture of about 1, 2, 3, 4, 5, 6, 7, 8, 9, 10, 11, 12, 13, 14, or 15% albumin (e.g., bovine serum albumin) or fetal bovine serum in PBS. In an embodiment, the sample fluid comprises about 1, 2, 3, 4, 5, 6, 7, 8, 9, 10, 11, 12, 13, 14, or 15% albumin (e.g., bovine serum albumin) or fetal bovine serum in PBS, while the active sheath fluid does not contain albumin or fetal bovine serum (e.g., the active sheath fluid is PBS).

Therefore, visualization of the difference between the cells or particles in active sheath fluid and the sample fluid can be enhanced where a cell compatible component (e.g., BSA, fetal bovine serum, etc.) is added to either solution as long as the refractive index and/or color of the two fluid compositions are different. The refractive indices of the two solutions can be less than 0.1% different. See, for example, FIG. 7. In an example the refractive indices of the two solutions can be less than 10, 5, 4, 3, 2, 1, 0.5, 0.1 or less different.

Active sheath fluid can flow at a rate of about 0.5 to about 50 μL or more (e.g., 5, 10, 15, 20, 30, 40, 50 μL/min. or more). In an embodiment, the active sheath fluid flow rate can be about twice as large as the sample flow rate and the sheath fluid flow can be about half the active sheath fluid flow rate. The active sheath fluid flowing though one or more active sheath fluid filled chambers can establish at active sheath fluid path, which can flow at different rates. The one or more active sheath fluid filled chambers can be positioned between an inlet microfluidic channel and one or more outlet microfluidic channels. In some embodiments, one or more active sheath fluid filled chambers can be positioned closer to the one or more outlet microfluidic channels. In some embodiments, the one or more active sheath fluid filled chambers can be positioned closer to the inlet microfluidic channel.

In some embodiments, the one or more active sheath fluid filled chambers are filled with active sheath fluid at a flow rate different from that of the sample fluid. As a result, the active sheath fluid from the one or more active sheath fluid filled chambers can embank the sample fluid causing the sample fluid to flow to an outlet microfluidic channel in line with (as opposed to at an angle to) the sample fluid line. In other words, the sample fluid flows to a center waste outlet and the sample fluid path is largely linear.

### Actuator

A microfluidic chip for sorting cells can include one or more actuators to push against the one or more active sheath fluid filled chambers, thereby controlling movement of active sheath fluid.

The microfluidic chip can include one or more actuator assemblies, which can be adjacent to the one or more active sheath fluid filled chambers. An actuator assembly can include an actuator, an elastic membrane, a controller, and a sensor. Thus, in some embodiments, the microfluidic chip can include an actuator assembly that relies on one or more feedback-controlled piezoelectric actuators to divert fluid paths (e.g., sample fluid path, active sheath fluid path, sheath fluid path) into the desired outlets.

An actuator can be a piezoelectric (piezo) actuator. Piezoelectric actuators are transducers that convert electrical energy into a mechanical displacement or stress based on a piezoelectric effect, or vice versa. Actuator configuration can vary greatly, depending on application. Piezoelectric stack or multilayer actuators are manufactured by stacking up piezoelectric disks or plates, the axis of the stack being the axis of linear motion that occurs when a voltage is applied. Tube actuators are monolithic devices that contract laterally and longitudinally when a voltage is applied between the inner and outer electrodes. A disk actuator is a device in the shape of a planar disk. Ring actuators are disk actuators with a center bore, making the actuator axis accessible for optical, mechanical, or electrical purposes. Other less common configurations include block, disk, bender, and bimorph styles.

Piezoelectric actuators can also be ultrasonic. Ultrasonic actuators are specifically designed to produce strokes of several micrometers at ultrasonic (>20 kHz) frequencies. They are especially useful for controlling vibration, positioning applications, and quick switching. In addition, piezoelectric actuators can be either direct or amplified. The effect of amplification is not only larger displacement, but it can also result in slower response times.

The critical specifications for piezoelectric actuators are displacement, force, and operating voltage of the actuator. Other factors to consider are stiffness, resonant frequency, and capacitance. Stiffness is a term used to describe the force needed to achieve a certain deformation of a structure. For piezoelectric actuators, it is the force needed to elongate the device by a certain amount, normally specified in terms of Newtons per micrometer. The force required to elongate a piezoelectric actuator can be about 100 to about 4,500 N/μM (e.g., about 100, 500, 1,000, 2,000, 3,000, 4,000, 4,500 N/μM or more. Resonance is the frequency at which the actuators respond with maximum output amplitude. The capacitance is a function of the excitation voltage frequency. A piezoelectric actuator can push against one or more active sheath fluid filled chambers to dispense an amount of active sheath fluid that diverts a portion of a sample fluid flowing along the sample flow path within the sample fluid line to a sorted outlet channel. Therefore, target cells or particles can be pushed to a sorted outlet to be collected while non-target cells or non-target particles can be flow to a waste outlet. A piezoelectric actuator can be removably in contact with an elastic membrane.

The actuator assembly can include a membrane. A membrane can be an elastic membrane and can be made of glass, polymer, plastic, or any other suitable material. A membrane can be embedded in the microfluidic chip with sufficient elasticity to return to a steady state each actuation. In some embodiments, a microscope coverslip can be utilized as a membrane. In an embodiment, a membrane can be in contact with a piezoelectric actuator based on a derivation of the sample fluid line. A membrane can be removable and not fused or permanently connected to the piezoelectric actuator.

The actuator assembly can include a controller. A controller can include a piezoelectric controller (piezoelectric actuator controller) that causes a piezoelectric actuator to engage with one or more active sheath fluid filled chambers in response to a trigger. A piezoelectric controller can provide voltage to a piezoelectric actuator and thus trigger actuation of the piezoelectric actuator. Voltage and waveform for piezoelectric actuator actuation can be adjusted and optimized to yield fast displacement of target cells, target particles, non-target cells, and/or non-target particles at a speed below 1 ms (e.g., 0.1, 0.2, 0.3, 0.5, 0.5, 0.6, 0.7, 0.8, 0.9, or 0.99 ms). Voltage and waveform for piezoelectric actuator actuation can also be adjusted and optimized to yield fast displacement of a target cell, a target particle, a non-target cell, and/or a non-target particle at a speed below 1 ms (e.g., 0.1, 0.2, 0.3, 0.5, 0.5, 0.6, 0.7, 0.8, 0.9, or 0.99 ms). When activated a piezoelectric actuator can push on an active sheath fluid filled chamber adjacent to said piezoelectric actuator, thus diverting active sheath fluid out. The dispersed (diverted) active sheath fluid path from the one or more active sheath fluid filled chambers can cause the sample fluid (in the sample fluid path) to divert to an angled outlet (i.e., a sorted outlet) on the opposite embankment.

An actuator assembly can include one or more sensors to gather the amount of force applied by one or more actuators (e.g., piezoelectric actuators) on one or more active sheath fluid filled chambers. In other words, a sensor (a “feedback sensor” or “a force (bias) feedback sensor”) can determine a contact force exerted by an actuator (e.g., a piezoelectric actuator) on an active sheath fluid filled chamber. Precise control is achieved by recording the amount of force exerted by a piezoelectric actuator on the adjacent active sheath fluid filled chamber and accordingly controlling its actuation. A feedback sensor records the contact force between the piezoelectric actuator and a membrane. Resistance on the feedback sensor can be between about 10 and about 100 kOhm (e.g., 10, 15, 20, 25, 30, 35, 40, 45, 50, 55, 60, 65, 70, 75, 80, 85, 90, 95, or 100 kOhm).

In some embodiments, an actuator assembly can include a bias screw configured to rotate up and down within a bias screw holder to establish an initial contact force with a membrane in contact with the piezoelectric actuator. In some embodiments, a motor can be coupled to a bias screw configured to establish an initial contact force with a membrane in contact with the piezoelectric actuator based on a derivation of the sample fluid in the sample fluid path. A bias screw can be configured to rotate up and down within a bias screw holder, wherein a downward rotation of the bias screw pushes the piezoelectric actuator to make contact with a membrane (e.g., an elastic membrane), which in turn can be deflected downward into the adjacent active sheath fluid filled chamber. In some embodiments, a bias screw holder can include a detachable unit that allows for reuse of the piezoelectric actuator, feedback sensor, and bias screw across multiple microfluidic chips. This lowers the cost of disposable microchips.

In some embodiments, an actuator assembly can include a piezo controller able to provide a voltage configured to trigger the piezoelectric actuator to elongate in proportion to the voltage, wherein a greater actuation voltage corresponds to greater elongation of an elongated piezoelectric actuator; and wherein the elongated piezoelectric actuator pushes against the membrane to deflect the membrane downward into the adjacent active sheath fluid filled chamber.

In some embodiments, the piezoelectric actuator can be configured to control the diversion of the portion of the sample fluid (flowing along a sample fluid path within a sample fluid line) into the sorted outlet channel by adjusting the contact force. The piezoelectric actuator can increase the contact force by increasing an actuation voltage to trigger the piezoelectric to elongate and/or changing a position of a bias screw configured to elongate the piezoelectric actuator. Actuation voltage can vary from, for example, about 5 to about 150V (e.g., about 5, 10, 15, 20, 25, 30, 35, 40, 45, 50, 55, 60, 65, 70, 75, 80, 85, 90, 95, 100, 105, 110, 115, 120, 125, 130, 135, 140, 145, or 150V).

In some embodiments, the actuator assembly can be integrated into a reusable unit that can be removed from the microfluidic chip.

In some embodiments, the microfluidic chip can include a trigger assembly connected to a piezoelectric controller, the trigger assembly can include an optical sensor that can detect a cell of interest in the sample fluid. An optical sensor can be placed above the sample fluid line (or other suitable position) nearby a microfluid inlet channel. The trigger assembly can be configured to transmit a trigger (e.g., an electric signal) to a piezoelectric controller in response to detecting one or more cells of interest in the sample fluid. For example, the trigger assembly can transmit the trigger to the piezoelectric controller in response to detecting one or more cells of interest in the sample fluid in the optical sensor field of view. Examples of assemblies that can detect cells or particles of interest in fluid are presented in US2021/0237064. The piezoelectric controller can actuate the piezoelectric actuator in response to receiving the trigger.

In some embodiments, actuation of the piezoelectric actuator can be timed by oversampling the field-of-view to capture the cells of interest in at least two consecutive frames. See e.g., U.S. Ser. No. 63/229,175 filed Aug. 4, 2021. Once a cell of interest is captured in at least two consecutive frames, the velocity of the sample fluid within the inlet microfluidic channel can be calculated. A travel time corresponding to a period of time required by the portion of sample fluid including the cell of interest to flow from the field of interest to the sorting zone can then be determined by based on a length of the sample fluid line (microfluidic channel) between the field of interest and the sorting zone and the velocity of the portion of sample fluid. For example, the length of the sample fluid line (microfluidic channel) can be divided by the velocity of the sample fluid. The trigger assembly can transmit the trigger to the piezoelectric controller after the travel time expires. In other embodiments, the piezoelectric controller can actuate the piezoelectric actuator when the determined travel time is expired.

In an aspect, the detection process can rely on a machine learning model to accurately identify the presence of the desired cells or particles. For a trigger to be issued, the cells or particles must meet the specified confidence level thresholds in multiple consecutive frames (e.g., 2, 3, 4, 5, 6, or more frames). The required confidence level for detection can vary between the initial frame and subsequent frames.

In some instances, a machine learning or artificial intelligence model can be trained using imaging (e.g., holographic imaging; see e.g., U.S. Ser. No. 63/363,422, filed Apr. 22, 2022; US Pat. Publ. 20230040252; and WO2021155322A1 all incorporated by reference herein) to distinguish target cells (e.g., CTCs) from other cell types (e.g., healthy cells or blood cells), or live cancer cells from dead cancer calls, etc. A fluorescent marker can act a confirmatory signal to further aid in weeding out false positives or false negatives by the model.

An algorithm, which can rely upon machine learning, can be configured to identify patterns of desirable target cells or particles in the sample. In some aspects, machine learning and/or artificial intelligence models can be utilized to develop and optimize the reference or control data so that target cells and particles can be identified. By way of example, samples of reference or control fluids, e.g., biological fluids can be analyzed to identify non-desirable constituents (e.g., non-target cells or non-target particles) of the biological fluid through machine learning. Such a system can be accomplished with relation to healthy cells, such as red blood cells, white blood cells, and the like. This is a result of consistency of the characteristics or images of such healthy cells and the availability of a large sample size. With respect to target cells or target particles, machine learning and/or artificial intelligence models can also be applied, though with a smaller sample size and with the caveat that certain unhealthy cells such as CTCs can have different characteristics in different patients. Additionally, the scanned data can also be analyzed using machine learning and/or artificial intelligence models. Furthermore, the process of comparing the scanned data with the reference data, and the resulting determination by a computer may also utilize machine learning and/or artificial intelligence models. See, e.g., US Pat. Publ. 20210237074, incorporated herein in its entirety.

In an aspect, captured image data may include a plurality of image frames. Each image frame may include a portion of the sample that was included in the field of view of the imager at a particular point in time when a piece of the image data was captured. The image frames and/or other image data captured by the camera may be processed by a machine learning system to identify the image frames that include one or more cells of interest. The machine learning system may be integrated into the trigger assembly and/or other component of the system of cell sorting. The machine learning system may also be a stand-alone hardware and/or software component of system. The machine learning system may include one or more machine learning models that may predict whether or not a particular image frame includes at least one of the cells of interest. For example, the machine learning system may include an image classifier or other machine learning model that processes the image frames captured by the camera to determine if a particular frame (fn) includes a cell or particle of interest. Once the machine learning system identifies the image frames that include the cells or particles of interest, the trigger assembly may operate to separate the cells or particles of interest from the other cells or particles included in the sample.

In an example, a system can receiving image data comprising one or multiple image frames of a sample including multiple cells or particles. The multiple image frames data can include image data of a portion of the multiple cells or particles included in the sample. A trigger can be generated for the image data or for each of the multiple image frames based on timing data corresponding to a capture time for the image data included in each of the image frames or multiple image frames. A frame of interest (e.g., a frame containing a cell or particle of interest) can be identified within the multiple image frames based on an output of a classification model. The cell or particle of interest can then be separated from the multiple cells or particles included in the sample by actuating a trigger assembly for the frame of interest. The classification model can be trained using a training dataset that includes multiple images labeled with different cell or particle types, wherein the output of the classification model includes a prediction for a cell or particle type of one or more cells or particles shown in the image data of the multiple image frames.

The classification model can be trained using a training dataset that includes multiple images labeled as including healthy cells and multiple images labeled as including other or unhealthy cells, wherein the output of the classification model includes a prediction of a type of one or more cells shown in the image data.

### Exemplary Embodiments

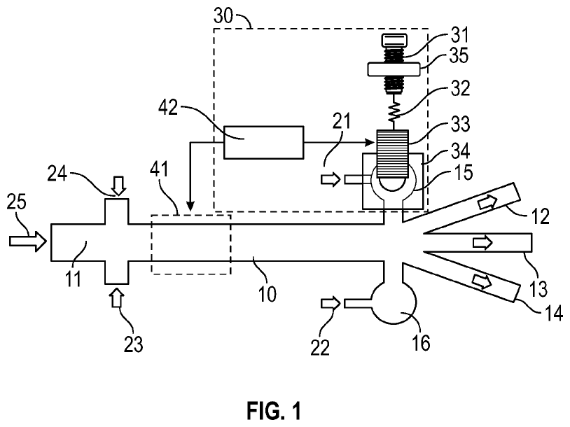

FIG. 1 shows a schematic of the microfluidic chip 10 for sorting cells showing the inlet microfluidic channel 11 to the sorting zone and an actuator assembly 30 adjacent to the sorting zone. In various embodiments, the sorting zone corresponds to a portion of the microfluidic channel where active sheath fluid 21, 22 from the one or more active sheath fluid filled chambers 15, 16 contacts the sample fluid 25 to divert a portion of the sample fluid 25. The actuator assembly 30 can include piezoelectric actuator 33 that pushes the target cells target particles of the sample fluid 15 to the sorted outlet 14, a bias screw 31, a bias screw holder 35, a feedback sensor 32, and a membrane 34 (e.g., an elastic membrane).

At baseline, the one or more active sheath fluid filled chambers 15, 16 can be filled with active sheath fluid 21, 22 at a flow rate different from that of the sample fluid 25. As a result, the active sheath fluid 21, 22 from the active sheath fluid filled chambers 15, 16 embank the sample fluid path causing the sample fluid 25 to flow to a center waste outlet 13.

When one or more cells of interest is detected in an optical sensor field of view 41, a piezoelectric controller 42 triggers to actuate a piezoelectric actuator 33. A piezoelectric actuator 33 pushes on the adjacent active sheath fluid filled chamber 15 and active sheath fluid 21 is diverted out, the dispersed active sheath fluid 21 from the adjacent active sheath fluid filled chamber 15 causes the sample fluid 25 to divert to a sorted outlet channel 14 that is on the opposite embankment of the active sheath fluid filled chamber 15.

A feedback sensor 32 is placed between the piezoelectric actuator 33 and a bias screw 31. A bias screw holder 35 can also be included. The bias screw 31 can be configured to rotate up and down within the bias screw holder 35 in response to an actuation voltage received from the piezoelectric actuator 33. Upon initial setup, the bias screw 31 is rotated to push down on the piezoelectric actuator 33 such that the piezoelectric actuator 33 touches and gently deflects a membrane 34 (e.g., an elastic membrane) downward into the active sheath fluid filled chamber 15. The feedback sensor 32 records an amount of force exerted by the bias screw 31 and the piezoelectric actuator 33. Upon actuation, as the piezoelectric actuator 33 elongates, it pushes against the membrane 34 (e.g., an elastic membrane) on one end and the feedback sensor 32 on the other end. Thus, during actuation, the feedback sensor 32 can record an increased force. This change is recorded and the position of the bias screw 31 and/or the actuating voltage are appropriately adjusted to provide the necessary deviation of the sample fluid 25 into the desired sorted outlet 14. This feedback mechanism compensates for variations in the size, shape, and/or position of one or more components of the actuator assembly 30. For example, variations that can occur during the manufacturing of the microfluidic chip 10, wearing of the piezoelectric actuator 33 or membrane 34 (e.g., an elastic membrane) during continued use, and the like.

The membrane 34 (e.g., an elastic membrane) can be a piece of elastic material that is embedded in the microfluidic chip 10. For example, the membrane 34 (e.g., an elastic membrane) can be positioned over or adjacent to one or more of the active sheath fluid filled chambers 15, 16. The elasticity of the membrane 34 (e.g., an elastic membrane) can enable the membrane 34 (e.g., an elastic membrane) to, when actuated by the piezoelectric actuator 33, flex in a direction opposite a contact force applied by the piezoelectric actuator 33 and to return to a steady state after each actuation. In some embodiments, a microscope coverslip can be utilized as the membrane 34 (e.g., an elastic membrane). As shown in FIG. 1, sheath fluid 23, 24 can be added though one or more focusing inlets (white arrows) and aid in further focusing the sample fluid 25 (and, by extension, sample fluid path) before the sample fluid 25 reaches the actuator assembly 30.

Also shown in FIG. 1, while the target cells/particles within the sample fluid 25 are collected in sorted outlet 14, the remainder of the sample fluid 25 can be collected in center waste outlet 13. Other outlet microfluidic channels can also be present such as upper outlet channel 12 as shown in FIG. 1. In some embodiments, upper outlet channel 12 can function as additional cell sorting outlet. In some embodiments, upper outlet channel 12 can function as an anticlog channel to clear any blockages in one or more inlet microfluidic channels 11. Clogs can be removed by blocking the other outlet microfluidic channels (e.g., sorted outlet 14 and center waste outlet 13) and forcing remaining fluid (e.g., sample fluid, active sheath fluid, sheath fluid) out of upper waste outlet 12.

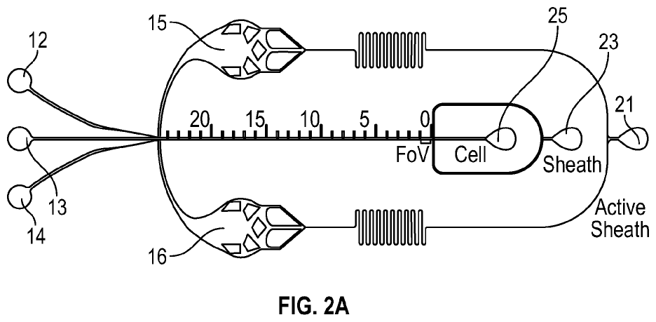

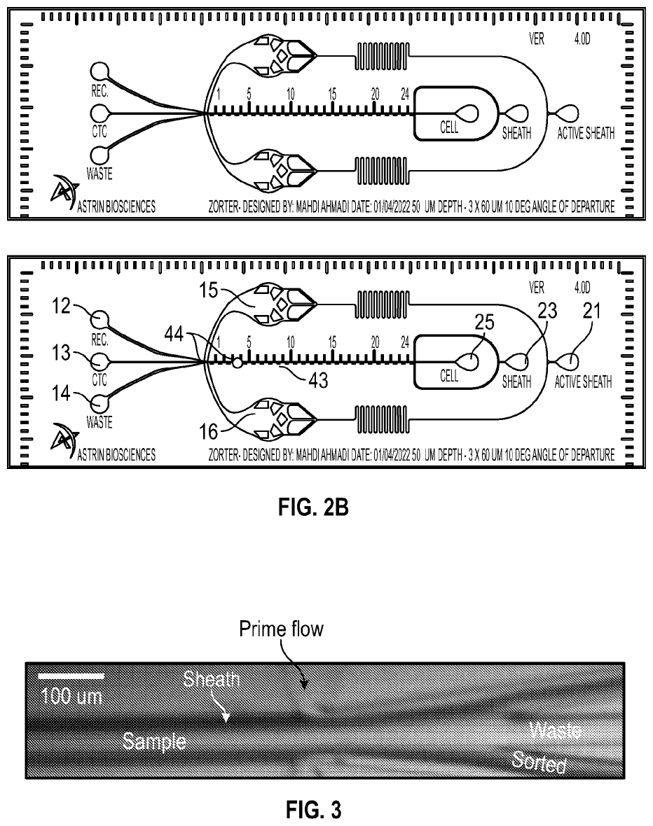

FIG. 2A-2B shows a design of the microfluidic chip 10 showing sample fluid 25, sheath fluid 23, and an active sheath fluid 21 having active sheath fluid path for sorting the target cells target particles (within a sample fluid 25) at right, one or more active sheath fluid filled chambers 15, 16 in center, and outlet microfluidic channels 12, 13, 14 at left. The active sheath fluid path travels in the field of view (FoV) 44 (at dot of 2B) under a microscope for detecting the target cells/particles in the sample fluid 25. The focusing inlets allow sheath fluid 23 to flow, which can focus the sample fluid 25. The active sheath fluid 21 flows to the one or more active sheath fluid filled chambers 15,16 in center of FIG. 2A-2B. The outlet microfluidic channels can remove blockage (e.g., upper waste outlet 12), collect waste (e.g., center waste outlet 13), and or sort target cells/particles of interest (e.g., sorted outlet 14). Furthermore, in any field of view 44 (at dot of 2B) with the size of interest, there can be a mark that codes the absolute distance to the piezoelectric actuator 33 that helps to time the actuation. The symbols 43 below the horizontal channel in FIG. 2B show the absolute distance between that location and the three outlet channels 12, 13, 14 at the left (labeled “Rec.,” ‘CTC,” and “Waste”). When the field of view is set (by, for example an optical sensor field of view 41), the system can identify the symbol and convert it to the distance from the outlet channels 12, 13, 14 at left.

FIG. 3 shows a fabricated single cell/particle sorting device: it shows sample fluid 25 (bright) at left that is covered by sheath (dark) fluid. Two active sheath fluid paths join from top and bottom and squeeze the sample fluid flowing though the sample fluid line, forming the sample fluid path, which flows into the center outlet (the waste outlet 13). At the right side the waste will go straight out, and the bottom line will collect the sorted cells/particles (the sorted outlet 14). The top channel is bidirectional and can be set to be an output or an input for removing blockage.

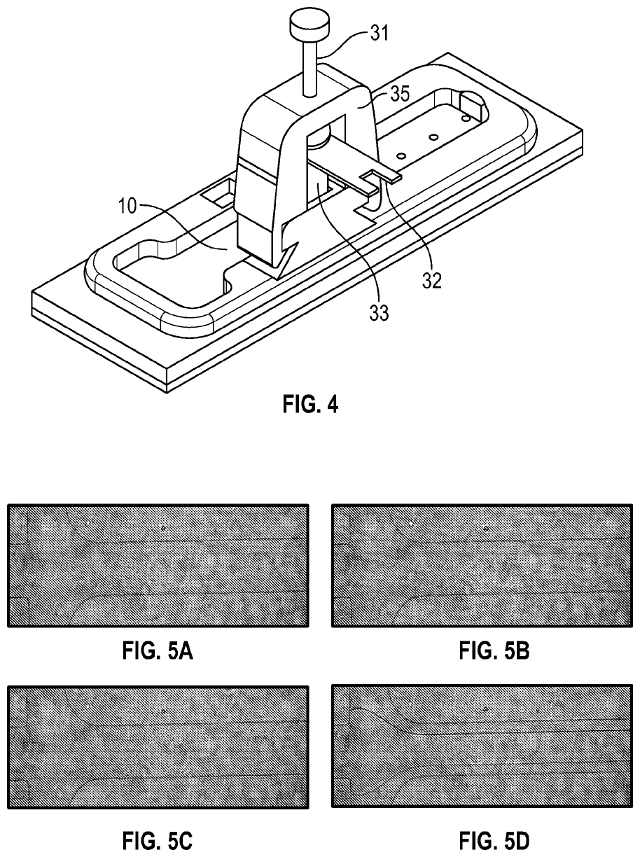

FIG. 4 shows an assembled microfluidic chip 10 with the bias screw 31, bias screw holder 35, feedback sensor 32 and the piezoelectric actuator 33. The feedback sensor 32 can be placed between the piezoelectric actuator 33 and the bias screw 31. Upon initial setup, the bias screw 31 can be rotated to push down on the piezoelectric actuator 33 to elongate the piezoelectric actuator 33 such that the piezoelectric actuator 33 touches and gently deflects a membrane 34 (e.g., an elastic membrane) downward into an adjacent active sheath fluid filled chamber 15.

Actuator assembly calibration can include establishing an initial bias for the bias screw 31 with the bias screw holder 35, recording force, and observing the extent of deviation of sample fluid from the center of the sample fluid line. With the derivation of sample fluid observed, the bias screw 31 can be adjusted accordingly, force can be recording again, and extent of deviation of sample fluid from the center (sample fluid path) can be observed. If deviation of sample fluid is insufficient to push sample fluid of the sample fluid path all the way to the desired outlet (e.g., sorted outlet 14, waste outlet 13, or multipurpose outlet 12), the bias of bias screw 31 can be adjusted to achieve desired derivation of sample fluid from the center (sample fluid path).

In some embodiments, the actuator assembly calibration be accomplished automatically using image processing and motorized screw. The feedback sensor 32 can record the amount of force exerted by the bias screw 31 and the piezoelectric actuator 33. Upon actuation, as the piezoelectric actuator 33 elongates, it pushes against the membrane 34 (e.g., an elastic membrane) on one end and the feedback sensor 32 on the other end. Thus, during actuation, the feedback sensor 32 records an increased force. This change is recorded and the bias screw 31 and/or the actuating voltage are appropriately adjusted to provide the necessary deviation of the sample fluid 25 into the desired outlet, such as the sorted outlet 14 (not shown in FIG. 4). Within some present limits so as not to cause turbulence, the bias screw 31 and actuating voltage 33 both help control the displacement of sample fluid flowing in a sample fluid path to the desired outlet (e.g., sorted outlet 14, waste outlet 13, or multipurpose outlet 12). Within some present limits so as not to cause turbulence can be that the actuation voltage 33 can vary from, for example, about 20 to about 100V (e.g., about 20, 40, 60, 70, 80, 100V or more) and resistance on the feedback sensor 32 can vary from about 20 to about 80 kOhm (e.g., about 20, 30, 40, 50, 60, 70, 80 kOhm or more). Such a feedback mechanism compensates for variations occurred during the manufacturing of the microfluidic chip 10 or the piezoelectric actuator 33 during continued use.

Bias screw holder 35 can include a detachable unit that includes the piezoelectric actuator 33, feedback sensor 32, and bias screw 31. The detachable unit can be attached and removed from a microfluidic chip 10 to allow for reuse of the piezoelectric actuator 33, feedback sensor 32, and bias screw 31 across multiple microfluidic chips 10. By enabling the reuse of multiple components of the actuator assembly 30, the detachable unit lowers the cost of disposable microfluidic chips.

As used herein, the term “subject” refers to any individual or patient on which the methods disclosed herein are performed. The term “subject” can be used interchangeably with the term “individual” or “patient.” The subject can be a human, although the subject can be an animal, as will be appreciated. Thus, other animals, including mammals such as rodents (including mice, rats, hamsters and guinea pigs), cats, dogs, rabbits, farm animals including cows, horses, goats, sheep, pigs, etc., and primates (including monkeys, chimpanzees, orangutans and gorillas) are included within the definition of subject.

As used herein, the term “and/or” includes any and all combinations of one or more of the associated listed items. As used in the description herein and throughout the claims that follow, the meaning of “a”, “an”, and “the” includes plural reference as well as the singular reference unless the context clearly dictates otherwise. The term “about” in association with a numerical value means that the value varies up or down by 5%. For example, for a value of about 100, means 95 to 105 (or any value between 95 and 105).

All patents, patent applications, and other scientific or technical writings referred to anywhere herein are incorporated by reference herein in their entirety. The embodiments illustratively described herein suitably can be practiced in the absence of any element or elements, limitation or limitations that are specifically or not specifically disclosed herein. Thus, for example, in each instance herein any of the terms “comprising,” “consisting essentially of,” and “consisting of” can be replaced with either of the other two terms, while retaining their ordinary meanings. The terms and expressions which have been employed are used as terms of description and not of limitation, and there is no intention that in the use of such terms and expressions of excluding any equivalents of the features shown and described or portions thereof, but it is recognized that various modifications are possible within the scope of the claims. Thus, it should be understood that although the present methods and compositions have been specifically disclosed by embodiments and optional features, modifications and variations of the concepts herein disclosed can be resorted to by those skilled in the art, and that such modifications and variations are considered to be within the scope of the compositions and methods as defined by the description and the appended claims.

Any single term, single element, single phrase, group of terms, group of phrases, or group of elements described herein can each be specifically excluded from the claims.

Whenever a range is given in the specification, for example, a temperature range, a time range, a composition, or concentration range, all intermediate ranges and subranges, as well as all individual values included in the ranges given are intended to be included in the disclosure. It will be understood that any subranges or individual values in a range or subrange that are included in the description herein can be excluded from the aspects herein. It will be understood that any elements or steps that are included in the description herein can be excluded from the claimed compositions or methods.

In addition, where features or aspects of the compositions and methods are described in terms of Markush groups or other grouping of alternatives, those skilled in the art will recognize that the compositions and methods are also thereby described in terms of any individual member or subgroup of members of the Markush group or other group.

### EXAMPLES

### Example 1: Albumin Containing Active Sheath Fluid for Visualization

A piezoelectric actuator bias can be more accurately set when the fluid paths (e.g., active sheath fluid path, sample fluid path, sheath fluid path, and the like) are visualized. This visualization can be done, for example, using color or a difference in refractive index to allow the boundary between the fluid paths (e.g., active sheath fluid path, sample fluid path, sheath fluid path, and the like) to be distinguished. Typically, different fluids are selected for their difference in refractive index such as isopropyl alcohol and water; however, many commonly used fluids (e.g., isopropyl alcohol or water) are incompatible with cells. Colored dyes such as crystal violet are biocompatible but can leak into sample (and/or the sorted outlet), which makes subsequent optical processing difficult.

For this study, it was determined that different concentrations of bovine serum albumin (BSA) dissolved in phosphate buffered saline (PBS) caused a large enough shift in the refractive index to be visible under the microscope. PBS is a salt solution designed specifically for cells. It does not provide nutrients but keeps the cells balanced such that they do not become hyper-or hypo-tonic. BSA is a serum protein derived from cows that is regularly used in both cell culture and other cellular assays to help stabilize the cells as well as decrease nonspecific interactions of the cells with their containers.

BSA levels in PBS from 0% to 7% were tested and compared with 0% BSA in the active sheath fluid path (FIG. 5). It was found that even 1% of BSA is visible but the active sheath fluid path is extremely faint. As BSA concentration increases, the boundary between the fluid paths (sample fluid and active sheath fluid) becomes more distinguishable and by 7% BSA the active sheath fluid path and sample fluid path are distinct (FIG. 5).

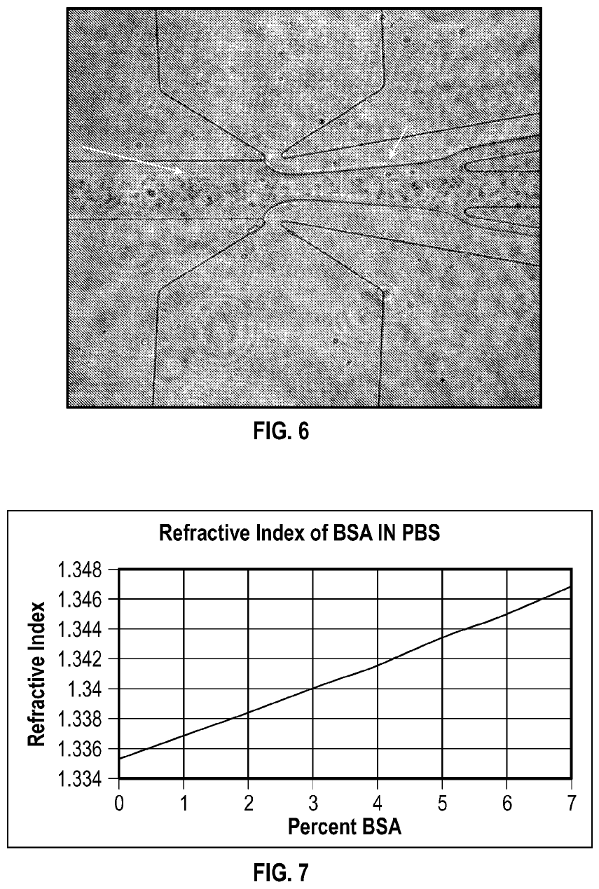

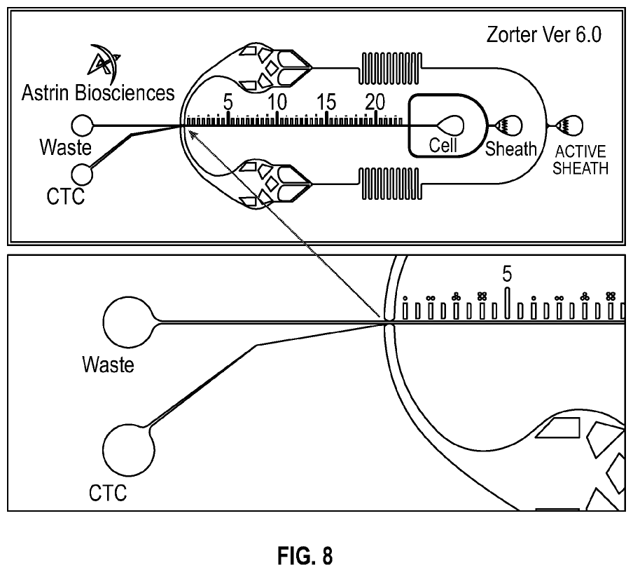

Addition of BSA or other suitable substance to active sheath fluid can enable visualization of sheath fluid, active sheath fluid, and cells in a cell sorting device. A BSA solution can be beneficial to survival of cells. Thus, the cells (sample fluid) were in 7% BSA, the sheath fluid was in 0% BSA, and the active sheath fluid was in 7% BSA. Using these conditions, all three fluid paths (active sheath fluid path, sheath fluid path, sample fluid path) can be visualized (FIG. 6). The boundary (see longer arrow) between the cell (within the sample fluid) and sheath fluid is still visible but is faint due to mixing at the edge as the sample flow path moved down the sample fluid line (FIG. 6). The boundary (shorter arrow) between the active sheath fluid and cell (within the sample fluid) is distinct since this is where active sheath fluid path enters the sample fluid path, which contains the target sample (e.g., cells). A small portion of the active sheath fluid flowed through the center channel and served to embank both the sheath and sample flow. Upon actuation, there is complete deviation of the active sheath flow.

1. A microfluidic chip for sorting cells, the microfluidic chip comprising:
a sample fluid line including an inlet microfluidic channel and multiple outlet microfluidic channels positioned opposite the inlet microfluidic channel, the multiple outlet microfluidic channels including one or more waste outlet channels and a one or more sorted outlet channels;
one or more active sheath fluid filled chambers placed at an angle to the sample fluid line; and
an actuator assembly adjacent to one of the one or more active sheath fluid filled chambers, the actuator assembly including:
a piezoelectric actuator that pushes against the one or more active sheath fluid filled chamber to dispense an amount of active sheath fluid that diverts a portion of a sample fluid to the one or more sorted outlet channels;
a piezoelectric controller that causes the piezoelectric actuator to engage with the one or more active sheath fluid filled chambers in response to a trigger; and
a feedback sensor that determines a contact force exerted by the piezoelectric actuator on the one or more active sheath fluid filled chambers.

2. The microfluidic chip of claim 1, wherein the actuator assembly further comprises:
a bias screw configured to rotate up and down within a bias screw holder to establish a contact force with a membrane in contact with the piezoelectric actuator;
an actuation voltage provided by the piezoelectric controller configured to trigger the piezoelectric actuator to elongate in proportion to the voltage, wherein a greater actuation voltage corresponds to greater elongation of an elongated piezoelectric actuator; and
wherein the elongated piezoelectric actuator pushes against the membrane to deflect the membrane downward into the one or more active sheath fluid filled chambers.

3. The microfluidic chip of claim 2, wherein the feedback sensor is disposed between the piezoelectric actuator and the bias screw, wherein the feedback sensor is configured to record an amount of force exerted by the bias screw and the piezoelectric actuator as the contact force exerted by the piezoelectric actuator on the one or more active sheath fluid filled chambers.

4. The microfluidic chip of claim 3, wherein the feedback sensor is further configured to, during actuation, record an increased amount of force exerted by the bias screw and the piezoelectric actuator, wherein an adjustment of the bias screw and/or an actuator voltage is based on the feedback sensor determining a change between the amount of force and the increased amount of force.

5. The microfluidic chip of claim 1, wherein the actuator assembly further comprises:
a motor coupled to a bias screw configured to establish a contact force with a membrane in contact with the piezoelectric actuator based on a derivation of the sample fluid in the sample fluid path;
an actuation voltage provided by the piezoelectric controller configured to trigger the piezoelectric actuator to elongate in proportion to the voltage, wherein a greater actuation voltage corresponds to greater elongation of an elongated piezoelectric actuator; and
wherein the elongated piezoelectric actuator pushes against the membrane to deflect the membrane downward into the one or more active sheath fluid filled chambers.

6. The microfluidic chip of claim 1, wherein the piezoelectric actuator is configured to control a diversion of the portion of the sample fluid into the one or more sorted outlet channels by adjusting the contact force.

7. The microfluidic chip of claim 6, wherein the piezoelectric actuator increases the contact force by increasing an actuation voltage or changing a position of a bias screw configured to elongate the piezoelectric actuator.

8. (canceled)

9. The microfluidic chip of claim 1, further comprising a trigger assembly connected to the piezoelectric controller, the trigger assembly including an optical sensor that detects a cell of interest in the sample; and
wherein the trigger assembly is configured to transmit the trigger to the piezoelectric controller in response to detecting the cell of interest.

10. The microfluidic chip of claim 9, wherein the trigger assembly is further configured to:
detect the cell of interest in at least two consecutive frames captured by the optical sensor;
calculate a velocity of the sample within the inlet microfluidic channel;
determine a travel time for the cell of interest between the optical sensor field of view and a sorting zone based on the velocity and a length of the microfluidic channel between the optical sensor field of view and the sorting zone; and
transmit the trigger to the piezoelectric controller when the travel time expires.

11. The microfluidic chip of claim 9, wherein the trigger assembly is further configured to:
detect the cell of interest at a position close to the one or more sorted outlet channels; and transmit the trigger to the piezoelectric controller when the cell of interest is detected such that the cell of interest is pushed into the one or more sorted outlet channels.

12. (canceled)

13. An actuator assembly for diverting a portion of a sample fluid, the actuator assembly integrated into a reusable unit that is configured to attach to a portion of a microfluidic chip,
the microfluidic chip including a sample fluid line including an inlet microfluidic channel and multiple outlet microfluidic channels positioned opposite the inlet microfluidic channel, the multiple outlet microfluidic channels including one or more waste outlet channels and one or more sorted outlet channels; and
one or more active sheath fluid filled chambers placed at an angle to the sample fluid line,
the actuator assembly adjacent to one of the one or more active sheath fluid filled chambers, the actuator assembly including:
a piezoelectric actuator that pushes against the one or more active sheath fluid filled chambers to dispense an amount of active sheath fluid that diverts a portion of a sample fluid to the one or more sorted outlet channels;
a piezoelectric controller that causes the piezoelectric actuator to engage with the one or more active sheath fluid filled chambers in response to a trigger; and
a feedback sensor that determines a contact force exerted by the piezoelectric actuator on the one or more active sheath fluid filled chambers.

14. The actuator assembly of claim 13 further comprising:
a bias screw configured to rotate up and down within a bias screw holder to establish a contact force with a membrane in contact with the piezoelectric actuator;
an actuation voltage provided by the piezoelectric controller configured to trigger the piezoelectric actuator to elongate in proportion to the voltage, wherein a greater actuation voltage corresponds to greater elongation of an elongated piezoelectric actuator; and
wherein the elongated piezoelectric actuator pushes against the membrane to deflect the membrane downward into the one or more active sheath fluid filled chambers.

15. The actuator assembly of claim 13 further comprising:
a motor coupled to a bias screw configured to establish a contact force with a membrane in contact with the piezoelectric actuator based on a derivation of the sample fluid in the sample fluid path;
an actuation voltage provided by the piezoelectric controller configured to trigger the piezoelectric actuator to elongate in proportion to the voltage, wherein a greater actuation voltage corresponds to greater elongation of an elongated piezoelectric actuator; and
wherein the elongated piezoelectric actuator pushes against the membrane to deflect the membrane downward into the one or more active sheath fluid filled chambers.

16. The actuator assembly of claim 15, wherein the feedback sensor is disposed between the piezoelectric actuator and the bias screw, wherein the feedback sensor is configured to:
record an amount of force exerted by the bias screw and the piezoelectric actuator as the contact force exerted by the piezoelectric actuator on the one or more active sheath fluid filled chambers; during actuation, record an increased amount of force exerted by the bias screw and the piezoelectric actuator; and
determine an adjustment of the bias screw and/or an actuator voltage based on a change between the amount of force and the increased amount of force.

17. The actuator assembly of claim 13, wherein the piezoelectric actuator is configured to control a diversion of the portion of the sample fluid into the one or more sorted outlet channels by adjusting the contact force.

18. The actuator assembly of claim 17, wherein the piezoelectric actuator increases the contact force by increasing an actuation voltage or changing a position of a bias screw configured to elongate the piezoelectric actuator.

19. The actuator assembly of claim 13, further comprising a trigger assembly connected to the piezoelectric controller, the trigger assembly including an optical sensor that detects a cell of interest in the sample; and
wherein the trigger assembly is configured to transmit the trigger to the piezoelectric controller in response to detecting the cell of interest.

20. The actuator assembly of claim 19, wherein the trigger assembly is further configured to:
detect the cell of interest in at least two consecutive frames captured by the optical sensor;
calculate a velocity of the sample within the inlet microfluidic channel;
determine a travel time for the cell of interest between a field of view of the optical sensor and a sorting zone based on the velocity and a length of the microfluidic channel between the optical sensor field of view and the sorting zone; and
transmit the trigger to the piezoelectric controller when the travel time expires.

21. (canceled)

22. A method for sorting cells, the method comprising:
inserting a sample into a sample fluid line in the microfluidic chip of claim 1, the sample fluid line including an inlet microfluidic channel that receives the sample and multiple outlet microfluidic channels positioned opposite the inlet microfluidic channel, the multiple outlet microfluidic channels including one or more waste outlet channels and one or more sorted outlet channels;
causing, by the piezoelectric controller, the piezoelectric actuator to push against one or more active sheath fluid filled chambers;
dispensing, by the piezoelectric actuator, an amount of active sheath fluid from the one or more active sheath fluid filled chambers to divert a portion of a sample fluid to the one or more sorted outlet channels; and
determining, by the feedback sensor, a contact force exerted by the piezoelectric actuator on the one or more active sheath fluid filled chambers.

23. The method of claim 22, wherein the microfluidic chip further includes a membrane in contact with the piezoelectric actuator and a bias screw within a holder, the method further comprising:
rotating the bias screw in a downward direction within the holder to elongate the piezoelectric actuator; and
deflecting, by the elongated piezoelectric actuator, the membrane downward into the one or more active sheath fluid filled chambers to dispense the amount of fluid from the one or more active sheath fluid filled chambers.

24-34. (canceled)
